(19) United States
(12) Patent Application Publication
(10) Pub. No.: US 2020/0100375 A1
(43) Pub. Date: Mar. 26, 2020

(54) TABLET SCREEN CONVERTIBLE DEVICE

(71) Applicant: Michael San Marzano, Queensland (AU)

(72) Inventor: Michael San Marzano, Queensland (AU)

(21) Appl. No.: 16/562,705

(22) Filed: Sep. 6, 2019

Related U.S. Application Data
(60) Provisional application No. 62/735,413, filed on Sep. 24, 2018.

(51) Int. Cl. H05K 5/02; A47B 23/04

(52) U.S. Cl. CPC H05K 5/0234; G06F 1/1626; A47B 23/044

(57) ABSTRACT

A tablet screen convertible device is provided allowing a user to position a computer tablet in the device such that the device arranges the computer tablet at the correct height and angle providing an ergonomic solution for the use of tablets. The device includes a tablet support member having a slot, wherein the slot is configured to receive a kickstand of the computer tablet. The device also includes a base member configured to hold a computer input device, such as a keyboard. The base member including at least one support element configured to position the tablet support member at a desired angle such that the computer tablet is in an ergonomic position.

### CROSS-REFERENCE TO RELATED APPLICATIONS

The present application claims priority to U.S. Provisional Application Ser. No. 62/735,413 filed on Sep. 24, 2018 entitled “TABLET SCREEN CONVERTIBLE DEVICE”, the disclosure of which is hereby incorporated in their entirety at least by reference.

### BACKGROUND OF THE INVENTION

### 1. Field of the Invention

The present invention generally relates to tablet screen, and more particularly to a tablet screen convertible device.

### 2. Description of Related Art

### BACKGROUND OF TEE INVENTION

Laptop personal computers (PCs) by necessity have been built with heavier components in a ‘base’ unit and a lighter display that can fold out and be held by friction hinges at various viewing angles. The proliferation of Tablet PCs presents a challenge in that the display is often incorporated into a single chassis with the heavier computing components. This often shifts the center of gravity in a hinged arrangement to the display, meaning some alternative configuration or additional support is required, or that friction hinges become impractical having to bear an increased load. There are existing solutions that simulate the traditional format and offer a tablet mode for use without a keyboard—however they do not offer any improvement to the configuration when the keyboard is in use. Most significantly the display unit is an uncomfortable distance from the viewer. Given the increasingly high resolution of digital displays and the growing dependence on mobile computing for work use, this is a considerable ergonomic/health issue. Consequently, there is a need for a tablet screen convertible device that allowing the tablet display screen to be held at an elevated position, closer to the user for a more ergonomic posture and viewing distance.

### BRIEF SUMMARY OF THE INVENTION

The following presents a simplified summary of some embodiments of the invention in order to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented later.

In one aspect of the invention, a tablet screen convertible device is provided, comprising a tablet support member having a slot, wherein the slot is configured to receive a kickstand of a computer tablet, wherein the computer tablet includes a display screen; and a base member configured to hold a computer input device, the base member including at least one support element configured to position the tablet support member at a desired angle such that the computer tablet is in an ergonomic position.

In one embodiment, the base member comprises a pair of support elements configured to work in conjunction with the table support member to support the computer tablet when attached to the tablet screen convertible device. In another embodiment, the base member further comprises a support bridge, wherein the support bridge is joined to the pair of support elements forming an integral support member. In another embodiment, the tablet support member includes a foldable connection member configured to be folded down over a portion of the pair of support elements and the support bridge keeping the tablet support member and the integral support member in the ergonomic positon during use. In yet another embodiment, the desired angle is in relation to the tablet support member and the pair of support elements.

In one embodiment, the pair of support elements is hingedly connected to the base member such that the pair of support elements can be folded down when not in use. In one embodiment, the tablet support member is constructed from a protective material. In another embodiment, the protective material is a polymer. In one embodiment, the computer input device is a wireless keyboard. In one embodiment, the tablet screen convertible device includes at least one handling by a user.

In another aspect of the invention, a tablet screen convertible device is provided, comprising a tablet support member having rails, wherein the rails are configured to receive a tablet; and a base member configured to hold a computer input device, the base member including at least one support elements configured to position the tablet support member at a desired angle such that the tablet is in an ergonomic position.

The foregoing has outlined rather broadly the more pertinent and important features of the present disclosure so that the detailed description of the invention that follows may be better understood and so that the present contribution to the art can be more fully appreciated. Additional features of the invention will be described hereinafter which form the subject of the claims of the invention. It should be appreciated by those skilled in the art that the conception and the disclosed specific methods and structures may be readily utilized as a basis for modifying or designing other structures for carrying out the same purposes of the present disclosure. It should be realized by those skilled in the art that such equivalent structures do not depart from the spirit and scope of the invention as set forth in the appended claims.

### BRIEF DESCRIPTION OF THE SEVERAL VIEWS OF THE DRAWINGS

Other features and advantages of the present invention will become apparent when the following detailed description is read in conjunction with the accompanying drawings, in which:

FIG. 1A is a front perspective view of a tablet screen convertible device according to an embodiment of the present invention;

FIG. 1B is a side perspective view of a tablet screen convertible device according to an embodiment of the present invention;

FIGS. 2A-C are method steps to operate a tablet screen convertible device according to an embodiment of the present invention;

FIG. 3 illustrates multiple perspective views illustrated the ergonomic positional advantages of the present invention compared to a traditional laptop; and,

FIG. 4 illustrates multiple perspective views an alternative tablet screen convertible device for tablets without kickstands according to an embodiment of the present invention.

### DETAILED DESCRIPTION OF THE PREFERRED EMBODIMENT

The following description is provided to enable any person skilled in the art to make and use the invention and sets forth the best odes contemplated by the inventor of carrying out their invention. Various modifications, however, will remain readily apparent to those skilled in the art, since the general principles of the present invention have been defined herein to specifically provide a tablet screen convertible device.

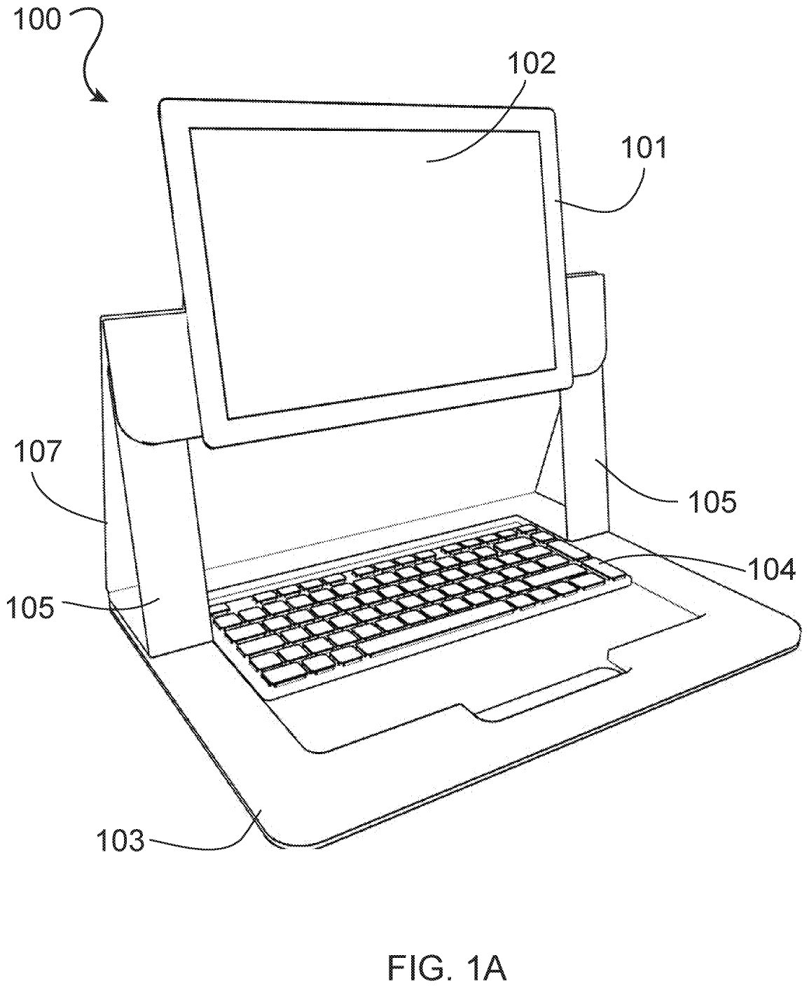

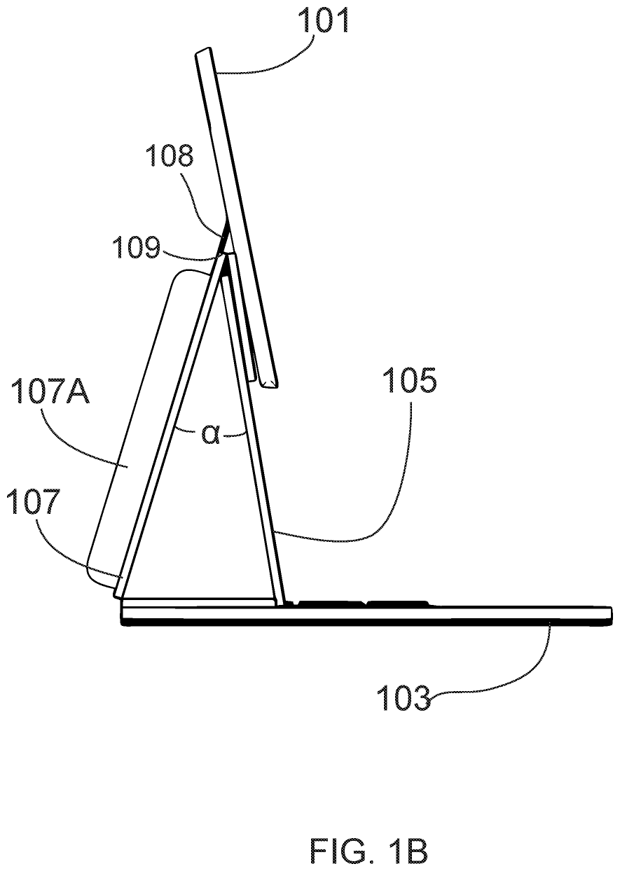

FIGS. 1A-B show perspective views of a tablet screen convertible device 100 according to an embodiment of the present invention. Referring now to FIGS. 1A-B, the tablet screen convertible device is illustrated. The tablet screen convertible device comprises a tablet support member 107 having a slot 109, wherein the slot is configured to receive a kickstand 108 of a kickstand tablet 101. The kickstand tablet includes a display screen 102 as well known in the art. The tablet support member is constructed from a protective material having a rectangular shape. In a preferred embodiment, the protective material is a polymer, but it is understood that any material may be used without departing from the spirit of the invention. The tablet screen convertible device further comprises a base member 103 configured to hold a computer input device 104. The computer input device is any input device known in the art, including but not limited to a keyboard, touchpad, and mouse. In a preferred embodiment, the computer input device is a wireless Bluetooth® keyboard. It should be understood that the computer input device is optional. In one embodiment, the base member is constructed from a protective material having a rectangular shape. It is a particular advantage of the present invention that the tablet screen convertible device is convertible into a carrying case, wherein the tablet support member and base member act as the carrying case. The protective material provided should be selected based on a variety of factors, including the ability to absorb forces from potential impacts without scratching or damaging the tablet screen.

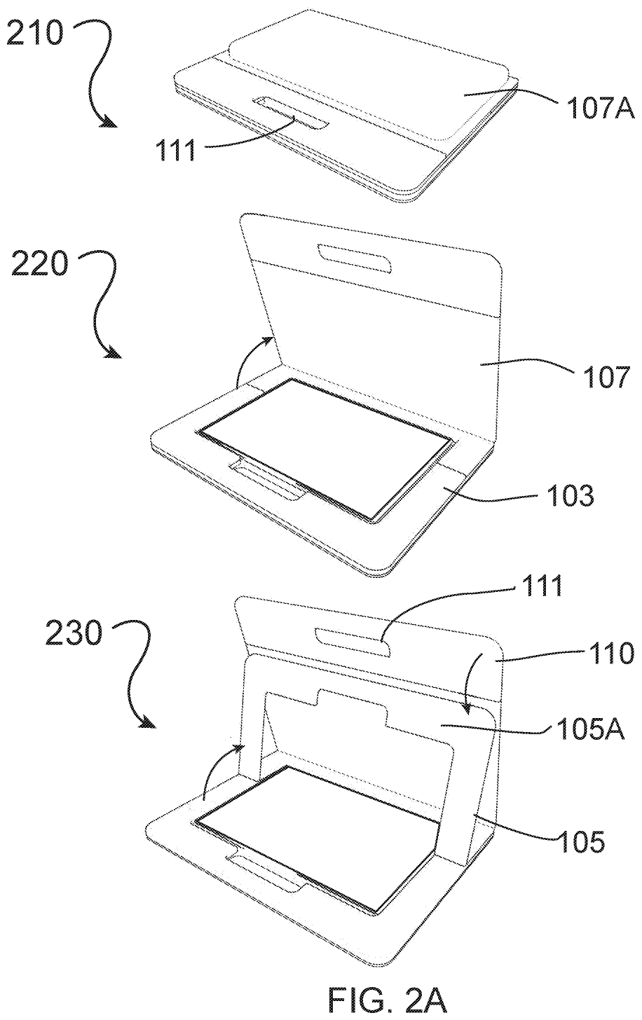

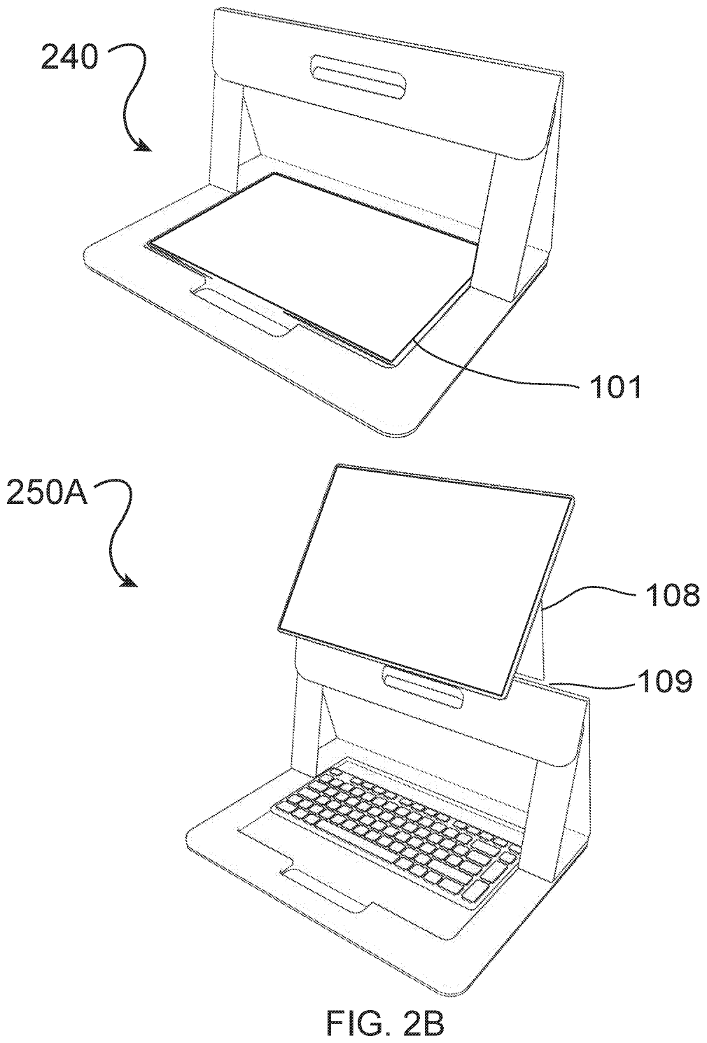

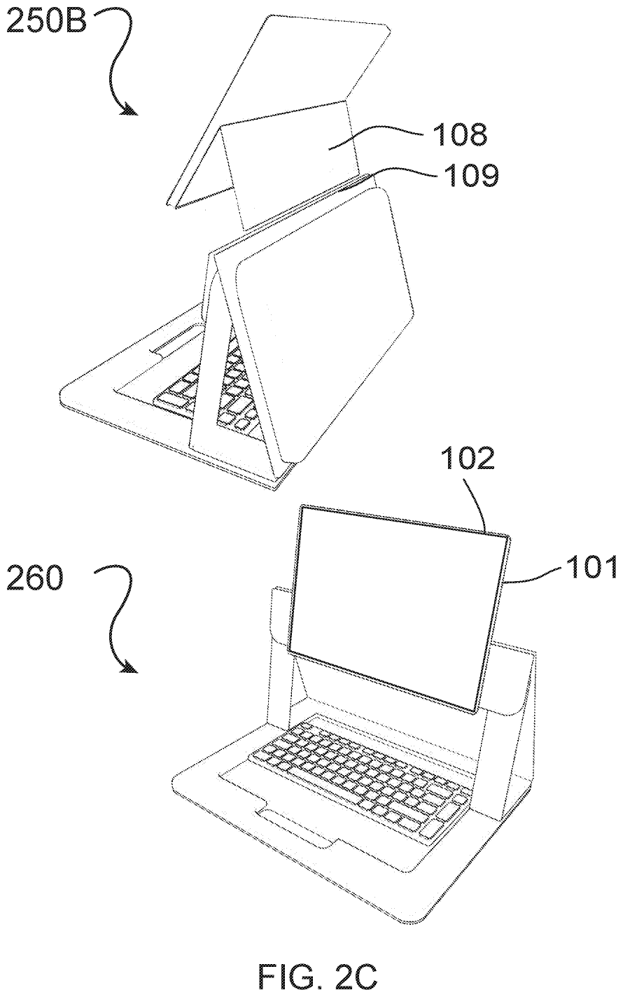

In one embodiment, the base member includes a pair of support elements 105 configured to work in conjunction with the tablet support member. In one embodiment, the pair of support elements are joined by a supporting bridge 105A providing extra support to the present invention (best seen in 203; FIG. 2). Best seen in FIG. 1B, this positions the tablet support member at a predetermined angle which is ideal for tablet screen height and angle from a user. It should be understood that the predetermined angle may vary. Referring to FIG. 1B, the predetermined angle is related to surfaces 107 and 105 of tablet support member and the pair support elements respectively, defined by α. In one embodiment, the pair of support elements is hingedly connected to the base member such that the pair of support elements can be folded down when not in use.

FIGS. 2A-C are method steps to operate a tablet screen convertible device according to an embodiment of the present invention, Referring now to FIGS. 2A-C the method is illustrated. In step 210, the tablet screen convertible device is in a carrying case position, which is a particular advantage of the present invention allowing the tablet screen convertible device to easily be stowed and transported. In one embodiment, at least one handle 111 is provided to facilitate carrying case as well known in the art. In alternative embodiments, no handle is provided. In one embodiment, a storage compartment is provided 107A on the back of the tablet support member. The storage compartment is useful to storage any tablet accessories, or any other objects the user desires. In one embodiment, the storage compartment is padded such that it protects the accessories and the tablet from damage.

In step 220, tablet support member 107 is separated from the base member 103. In one embodiment, an attachment means (not shown) is provided to secure the tablet support member and base member together in the carrying case position. In one embodiment, the attachment means is any attachment means known in the art, including but not limited to a magnetic connection, snaps, latches, Velcro, or buckle.

In step 230, the pair of support elements 105 is put in position, wherein a foldable connecting member 110 is folded down over the pair of support elements and support bridge 105A. In one embodiment, there are connection elements configured to fasten the foldable connecting member to the pair of support elements keeping all the components in position during use.

In step 240, the kickstand tablet 101 is removed from the base member. In step 250, the kickstand 108 of the kickstand tablet is inserted into the slot 109. This is shown in a front 250A and rear 250B perspective illustration.

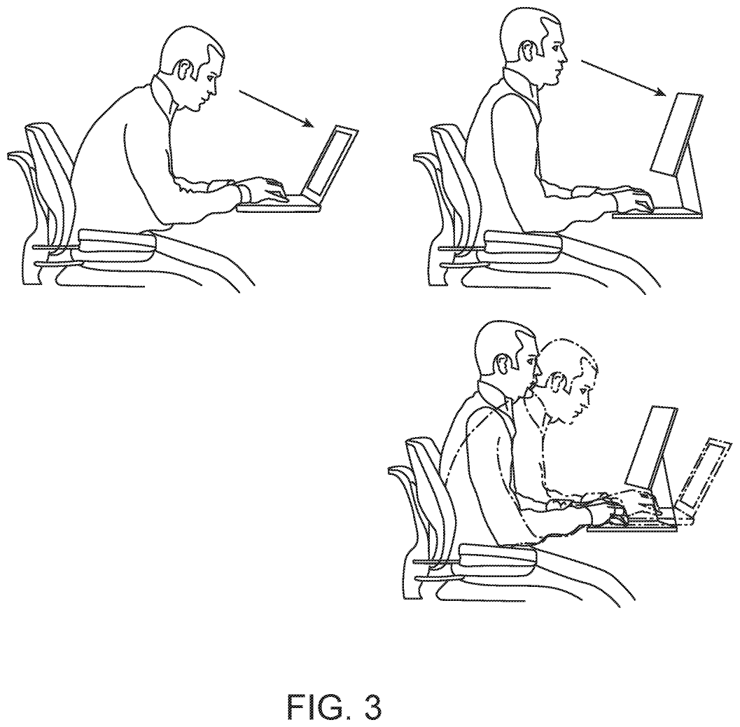

In step 260, the tablet screen convertible device 100 is operational. In this position, the kickstand tablet 101 is elevated, bringing the display screen 102 nearer to the face of a user, allowing for more upright posture and a better ergonomic position than a traditional laptop (FIG. 3). In this position, the angle of the display screen can also be adjusted or tilted based on the preferences of the user.

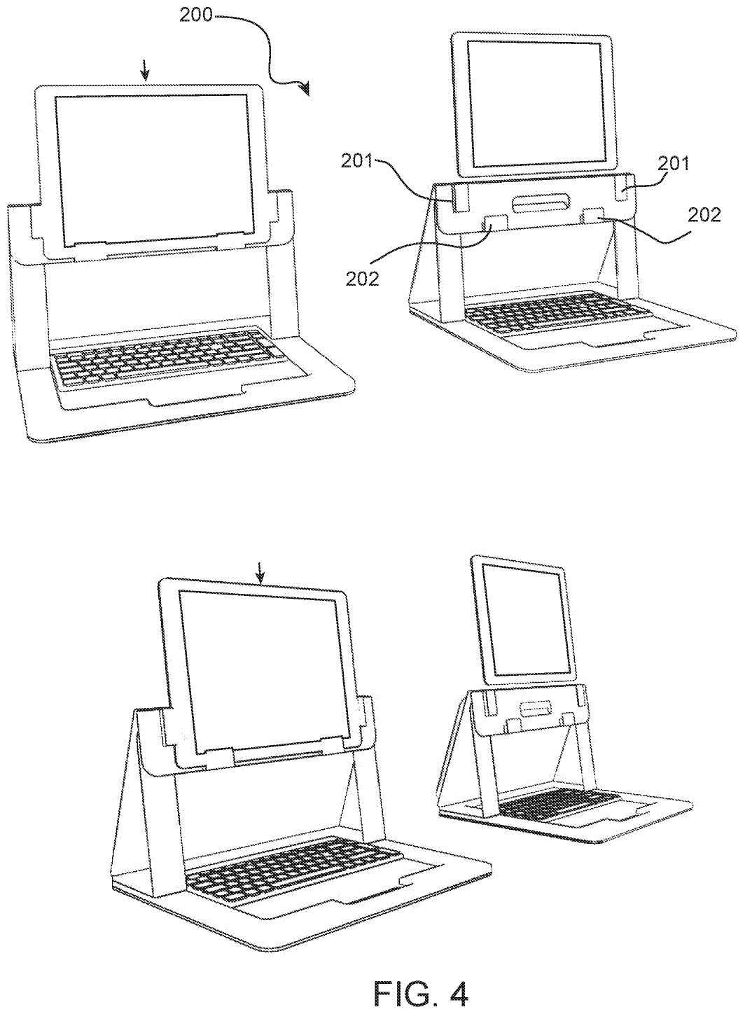

FIG. 4 illustrates multiple perspective views an alternative tablet screen convertible device 200 for tablets without kickstands according to an embodiment of the present invention. Retelling now to FIG. 4, the alternative tablet screen convertible device comprises a series of rails, specifically vertical rails 201 and horizontal rails 202. Advantageously, if a tablet does not include a kickstand, the tablet is simply held by the rails in position during use.

Although the invention has been described in considerable detail in language specific to structural features and or method acts, it is to be understood that the invention defined in the appended claims is not necessarily limited to the specific features or acts described. Rather, the specific features and acts are disclosed as exemplary preferred forms of implementing the claimed invention. Stated otherwise, it is to be understood that the phraseology and terminology employed herein, as well as the abstract, are for the purpose of description and should not be regarded as limiting. Therefore, while exemplary illustrative embodiments of the invention have been described, numerous variations and alternative embodiments will occur to those skilled in the art. Such variations and alternate embodiments are contemplated, and can be made without departing from the spirit and scope of the invention.

It should further be noted that throughout the entire disclosure, the labels such as left, right, front, back, top, bottom, forward, reverse, clockwise, counter clockwise, up, down, or other similar terms such as upper, lower, aft, fore, vertical, horizontal, oblique, proximal, distal, parallel, perpendicular, transverse, longitudinal, etc. have been used for convenience purposes only and are not intended to imply any particular fixed direction or orientation. Instead, they are used to reflect relative locations and/or directions/orientations between various portions of an object.

In addition, reference to “first,” “second,” “third,” and etc. members throughout the disclosure (and in particular, claims) are not used to show a serial or numerical limitation but instead are used to distinguish or identify the various members of the group.

What is claimed is:

1. A tablet screen convertible device comprising:
a tablet support member having a slot, wherein the slot is configured to receive a kickstand of a computer tablet, wherein the computer tablet includes a display screen; and
a base member configured to hold a computer input device, the base member including at least one support element configured to position the tablet support member at a desired angle such that the computer tablet is in an ergonomic position.

2. The tablet screen convertible device of claim 1, wherein the base member comprises a pair of support elements configured to work in conjunction with the table support member to support the computer tablet when attached to the tablet screen convertible device.

3. The tablet screen convertible device of claim 2, wherein the base member further comprises a support bridge, wherein the support bridge is joined to the pair of support elements forming an integral support member.

4. The tablet screen convertible device of claim 3, wherein the tablet support member includes a foldable connection member configured to be folded down over a portion of the pair of support elements and the support bridge keeping the tablet support member and the integral support member in the ergonomic positon during use.

5. The tablet screen convertible device of claim 4, wherein the desired angle is in relation to the tablet support member and the pair of support elements.

6. The tablet screen convertible device of claim 2, wherein the pair of support elements is hingedly connected to the base member such that the pair of support elements can be folded down when not in use.

7. The tablet screen convertible device of claim 1, wherein the tablet support member is constructed from a protective material.

8. The table screen convertible device of claim 7, wherein the protective material is a polymer.

9. The tablet screen convertible device of claim 1, wherein the computer input device is a wireless keyboard.

10. The tablet screen convertible device of claim 1, wherein the tablet screen convertible device includes at least one handling by a user.

11. A tablet screen convertible device comprising:
a tablet support member having rails, wherein the rails are configured to receive a tablet; and
a base member configured to hold a computer input device, the base member including a at least one support elements configured to position the tablet support member at a desired angle such that the tablet is in an ergonomic position.
